(19) United States
(12) Patent Application Publication
(10) Pub. No.: US 2005/0255666 A1
(43) Pub. Date: Nov. 17, 2005

(54) Method and structure for aligning mechanical based device to integrated circuits

(75) Inventor: Xiao Charles Yang, Sunnyvale, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Miradia Inc., Santa Clara, CA (US)

(21) Appl. No.: 10/843,793

(22) Filed: May 11, 2004

(51) Int. Cl. H01L 29/76; H01L 29/94; H01L 31/062; H01L 31/113; H01L 31/119; H01L 21/76; H01L 21/30; H01L 21/46

(52) U.S. Cl. 438/401; 438/455

(57) ABSTRACT

A method for bonding substrates together. The method includes providing a first substrate comprising a first surface. The first substrate comprises a plurality of first chips thereon. Each of the chips has integrated circuit devices. The first substrate includes a first alignment mark on the first substrate and a second alignment mark on the first substrate. The method also includes providing a second substrate comprising a silicon bearing material and second surface. The second substrate comprising a plurality of second chips thereon. Each of the chips comprises a plurality of mechanical structures. The second substrate has a first silicon based pattern on the second substrate and a second silicon based pattern on the second substrate. The method includes moving the first alignment mark of the first substrate to the first silicon based pattern on the second substrate and aligning the second alignment mark of the first substrate to the second silicon based pattern on the second substrate. A portion of at least one of the first substrate or the second substrate is illuminated with electromagnetic radiation. The method includes detecting a portion of the electromagnetic radiation and using the detected portion of the electromagnetic radiation to align the first substrate with the second substrate. The method also includes coupling the first substrate with the second substrate by contacting the first surface with the second surface and bonding the first surface with the second surface.

### BACKGROUND OF THE INVENTION

The present invention relates generally to bonding techniques. More particularly, the invention includes a method and structure for bonding substrates together using alignment marks. Merely by way of example, the invention has been applied to integrating a mechanical based structure with an integrated circuit chip. But it would be recognized that the invention has a much broader range of applicability.

Visual display technologies have rapidly developed over the years. Most particularly, electronic displays for outputting television shows, streaming video, and the like. From the early days, cathode ray tube technology, commonly called CRTs, outputted selected pixel elements onto a glass screen in conventional television sets. These television sets originally output black and white moving pictures. Color television sets soon replaced most if not all black and white television units. Although very successful, CRTs were often bulky, difficult to make larger, and had other limitations.

CRTs were soon replaced, at least in part, with liquid crystal panel displays. These liquid crystal panel displays commonly called LCDs used an array of transistor elements coupled to a liquid crystal material and color filter to output moving pictures in color. Many computer terminals and smaller display devices often relied upon LCDs to output video, text, and other visual features. Unfortunately, liquid crystal panels often had low yields and were difficult to scale up to larger sizes. These LCDs were often unsuitable for larger displays often required for television sets and the like.

Accordingly, projection display units have been developed. These projection display units include, among others, a counterpart liquid crystal display, which outputs light from selected pixel elements through a lens to a larger display to create moving pictures, text, and other visual images. Another technology is called “Digital Light Processing” (DLP), which is a commercial name from Texas Instruments Incorporated (TI) of Texas, USA. DLP is often referred to as the use of “micro-mirrors.” DLP relies upon a few hundred thousand tiny mirrors, which line up in 800 rows of 600 mirrors each. Each of the mirrors is hinged. An actuator is attached to each of the hinges. The actuator is often electrostatic energy that can tilt each of the mirrors at high frequency. The moving mirrors can modulate light, which can be transmitted through a lens and then displayed on a screen. Although DLP has been successful, it is often difficult to manufacture and subject to low yields, etc. DLP is also manufactured using MEMS based processing techniques. Such MEMS based processing technique is often costly and difficult to scale up for efficient processing.

From the above, it is seen that an improved technique for processing devices is desired.

### BRIEF SUMMARY OF THE INVENTION

According to the present invention, techniques for bonding substrates are provided. More particularly, the invention includes a method and structure for bonding substrates together using alignment marks. Merely by way of example, the invention has been applied to integrating a mechanical based structure with an integrated circuit chip. But it would be recognized that the invention has a much broader range of applicability.

In a specific embodiment, the invention provides a method for bonding substrates together. The method includes providing a first substrate comprising a first surface. The first substrate comprises a plurality of first chips thereon. Each of the chips has integrated circuit devices. The first substrate includes a first alignment mark on the first substrate and a second alignment mark on the first substrate. The method also includes providing a second substrate comprising a silicon bearing material and second surface. The second substrate comprising a plurality of second chips thereon. Each of the chips comprises a plurality of mechanical structures. The second substrate has a first silicon based pattern on the second substrate and a second silicon based pattern on the second substrate. The method includes moving the first alignment mark of the first substrate to the first silicon based pattern on the second substrate and aligning the second alignment mark of the first substrate to the second silicon based pattern on the second substrate. A portion of at least one of the first substrate or the second substrate is illuminated with electromagnetic radiation. The method includes detecting a portion of the electromagnetic radiation and using the detected portion of the electromagnetic radiation to align the first substrate with the second substrate. The method also includes coupling the first substrate with the second substrate by contacting the first surface with the second surface and bonding the first surface with the second surface. Preferably, the method holds the first substrate with a first vacuum chuck to substantially contact a backside of the first substrate to the first vacuum chuck and holds the second substrate with a second vacuum chuck to substantially contact a backside of the second substrate to the second vacuum chuck.

In an alternative specific embodiment, the invention provides a method for bonding different substrates together to manufacture display devices for visual imaging applications. The method includes providing a first substrate comprising a first surface, the first substrate comprising a plurality of first chips thereon. Each of the chips comprises integrated circuit devices. Preferably, the first substrate comprises a first alignment mark on the first substrate and a second alignment mark on the first substrate. The method also includes providing a second substrate comprising a silicon bearing material and second surface. The second substrate comprises a plurality of second chips thereon. Each of the chips comprising a plurality of mechanical mirror structures. The second substrate comprises a first silicon based pattern on the second substrate and a second silicon based pattern on the second substrate. The method includes moving the first alignment mark of the first substrate to the first silicon based pattern on the second substrate and moving the second alignment mark of the first substrate to the second silicon based pattern on the second substrate. The method maintains substantial parallel alignment between the first surface and the second surface during a portion of time associated with moving the first alignment mark to the first silicon based pattern and moving the second alignment mark with the second silicon based pattern. The method illuminates a portion of at least one of the first substrate or the second substrate with electromagnetic radiation while the first surface is in substantial parallel alignment with the second substrate. The method also detects a signal associated with a portion of the electromagnetic radiation and uses the signal associated with the detected portion of the electromagnetic radiation to align the first substrate with the second substrate using at least the first alignment mark and the first silicon based pattern or the second alignment mark and the second silicon based pattern. The method couples the first substrate with the second substrate by contacting the first surface with the second surface. Next, the method initiates a bond between the first surface with the second surface.

Many benefits are achieved by way of the present invention over conventional techniques. For example, the present technique provides an easy to use process that relies upon conventional technology. In some embodiments, the method provides higher device yields for the bonded substrates. Additionally, the method provides a process that is compatible with conventional process technology without substantial modifications to conventional equipment and processes. Preferably, the invention provides for an improved integrated structure including integrated circuits and mirror structures for display applications. Preferably, infrared radiation (IR) is used to allow for improved alignment accuracy and may include other benefits. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1 through 3 illustrate a method for bonding a pair of substrates together using simplified cross-sectional view diagrams of substrates according to embodiments of the present invention.

### DETAILED DESCRIPTION OF THE INVENTION

According to the present invention, techniques for bonding substrates are provided. More particularly, the invention includes a method and structure for bonding substrates together using alignment marks. Merely by way of example, the invention has been applied to integrating a mechanical based structure with an integrated circuit chip. But it would be recognized that the invention has a much broader range of applicability.

A method for bonding a pair of substrates together according to an embodiment of the present invention may be outlined as follows:
1. Provide a first substrate comprising a first surface and a plurality of first chips including integrated circuit devices thereon, whereupon the first substrate includes a first alignment mark on the first substrate and a second alignment mark on the first substrate;
2. Provide a second substrate comprising a silicon bearing material and second surface including a plurality of second chips including a plurality of mechanical structures, whereupon the second substrate has a first silicon based pattern on the second substrate and a second silicon based pattern on the second substrate;
3. Move the first alignment mark of the first substrate to the first silicon based pattern on the second substrate;
4. Move the second alignment mark of the first substrate to the second silicon based pattern on the second substrate;
5. Complete initial alignment of the first alignment mark to the first silicon based pattern;
6. Complete initial alignment of the second alignment mark to the second silicon based pattern;
7. Illuminate a portion of at least one of the first substrate or the second substrate with electromagnetic radiation;
8. Detect a portion of the electromagnetic radiation and using the detected portion of the electromagnetic radiation;
9. Complete alignment of the first substrate with the second substrate;
10. Couple the first substrate with the second substrate by contacting the first surface with the second surface;
Initiate a bond between the first surface with the second surface;
12. Complete the bond between the first substrate and the second substrate; and
13. Perform other steps, as desired.

The above sequence of steps provides a method for bonding a pair of substrates together according to an embodiment of the present invention. As shown, the method uses a combination of steps including a way of bonding two substrates of different type together for a display device having a plurality of movable mirror structures. Other alternatives can also be provided where steps are added, one or more steps are removed, or one or more steps are provided in a different sequence without departing from the scope of the claims herein. Further details of the present method can be found throughout the present specification and more particularly below.

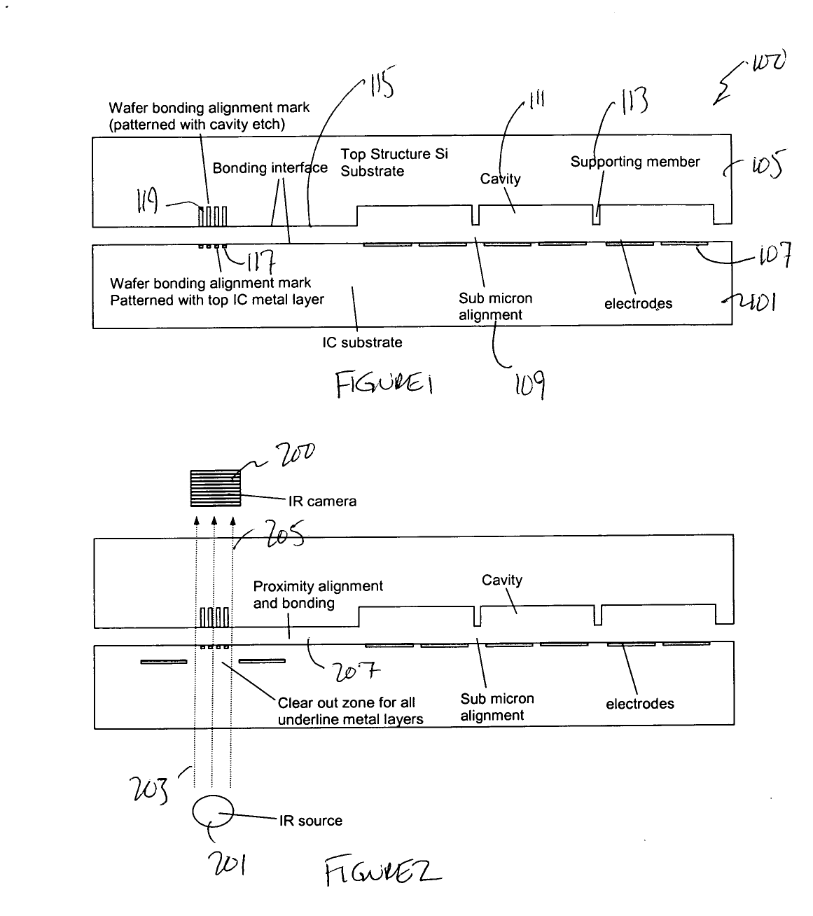

FIGS. 1 through 3 illustrate a method 100 for bonding two different substrates together for forming a display device according to an embodiment of the present invention. These diagrams are merely examples, which should not unduly limit the scope of the claims herein. One of ordinary skill in the art would recognize many variations, alternatives, and modifications. As shown, the method is for bonding different substrates together to manufacture display devices for visual imaging applications, e.g., mirror based displays. The method includes providing a first substrate 101 comprising a first surface, which has a plurality of first chips thereon. Each of the chips comprises integrated circuit devices. Preferably, the first substrate comprises a first alignment mark 117 on the first substrate and a second alignment mark (not shown but on the other edge of the substrate) on the first substrate. Preferably, the first alignment mark and the second alignment mark are spaced from each other at opposite ends of the first surface, which is the substrate face. The first substrate also includes a plurality of electrodes 107 thereon. Preferably, the first and second alignment marks and the electrodes are made using the same layer, e.g., patterned aluminum. Further details of such substrate structure can be found at U.S. patent application Ser. No. 10/718,482, filed Nov. 19, 2003, commonly owned, and hereby incorporated by reference for all purposes.

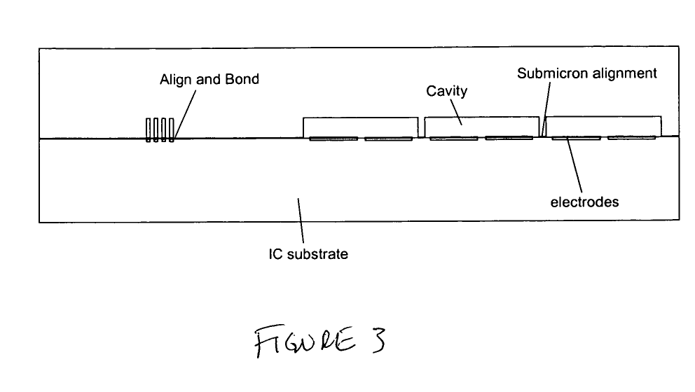

The method also includes providing a second substrate 105 comprising a silicon bearing material and second surface 115. Preferably, the second substrate is a silicon wafer or silicon on insulator wafer. The second substrate comprises a plurality of second chips thereon. Each of the chips comprising a plurality of mechanical mirror structures. The second substrate comprises a first silicon based pattern 119 on the second substrate and a second silicon based pattern on the second substrate. Preferably, each of the substrates has a polished face side that has been polished using chemical mechanical polishing, chemical smoothing, and/or other techniques. Other than silicon based substrates, other substrates can also be used. These substrates can include glass, germanium, multilayered materials, group IV materials, and the like. The method includes moving the first alignment mark of the first substrate to the first silicon based pattern on the second substrate and moving the second alignment mark of the first substrate to the second silicon based pattern on the second substrate, as illustrated by FIG. 2.

Preferably, the method maintains substantial parallel alignment between the first surface and the second surface during a portion of time associated with moving the first alignment mark to the first silicon based pattern and moving the second alignment mark with the second silicon based pattern. In a preferred embodiment, the method maintains the first alignment mark of the first substrate within about 40 microns or less of the first silicon based pattern on the second substrate and maintains the second alignment mark of the first substrate within about 40 microns or less of the second silicon based pattern on the second substrate. Preferably, the spacing can also be 20 microns and less or 10 microns and less, depending upon the embodiment.

As shown, the method illuminates 203 a portion of at least one of the first substrate or the second substrate with electromagnetic radiation source 201 (i.e., infrared) while the first surface is in substantial parallel alignment with the second substrate. The method also detects via detector 200 a signal 205 associated with a portion of the electromagnetic radiation and uses the signal associated with the detected portion of the electromagnetic radiation to align the first substrate with the second substrate using at least the first alignment mark and the first silicon based pattern or the second alignment mark and the second silicon based pattern. The method couples the first substrate with the second substrate by contacting the first surface with the second surface as shown in FIG. 3. Next, the method initiates a bond between the first surface with the second surface. Depending upon the embodiment, there can also be other steps, which are added or replaced.

It is also understood that the examples and embodiments described herein are for illustrative purposes only and that various modifications or changes in light thereof will be suggested to persons skilled in the art and are to be included within the spirit and purview of this application and scope of the appended claims.

1. A method for bonding substrates together to manufacture display devices for visual imaging applications, the method comprising:
providing a first substrate comprising a first surface, the first substrate comprising a plurality of first chips thereon, each of the chips comprising integrated circuit devices, the first substrate comprising a first alignment mark on the first substrate and a second alignment mark on the first substrate;
providing a second substrate comprising a silicon bearing material and second surface, the second substrate comprising a plurality of second chips thereon, each of the chips comprising a plurality of mechanical structures, the second substrate comprising a first silicon based pattern on the second substrate and a second silicon based pattern on the second substrate;
holding the first substrate with a first vacuum chuck to substantially contact a backside of the first substrate to the first vacuum chuck;
holding the second substrate with a second vacuum chuck to substantially contact a backside of the second substrate to the second vacuum chuck;
moving the first alignment mark of the first substrate to the first silicon based pattern on the second substrate and aligning the second alignment mark of the first substrate to the second silicon based pattern on the second substrate;
maintaining the first alignment mark of the first substrate within about 40 microns or less of the first silicon based pattern on the second substrate;
maintaining the second alignment mark of the first substrate within about 40 microns or less of the second silicon based pattern on the second substrate;
illuminating a portion of at least one of the first substrate or the second substrate with electromagnetic radiation;
detecting a portion of the electromagnetic radiation;
using the detected portion of the electromagnetic radiation to align the first substrate with the second substrate;
coupling the first substrate with the second substrate by contacting the first surface with the second surface; and
bonding the first surface with the second surface.

2. The method of claim 1 wherein the electromagnetic radiation comprises infrared radiation.

3. The method of claim 1 wherein the first alignment mark and the second alignment mark comprise patterned aluminum.

4. The method of claim 1 wherein the coupling brings the first face in contact with the second face using an action in a direction normal to the first surface and the second surface.

5. The method of claim 4 wherein the coupling occurs using only the normal direction for a distance of less than 30 microns.

6. The method of claim 1 wherein the bonding occurs using room temperature.

7. The method of claim 1 wherein the bonding further comprises annealing the first substrate and the second substrate to permanently bond the first surface to the second surface.

8. The method of claim 1 wherein the first surface comprises a deposited oxide, the deposited oxide being planarized.

9. The method of claim 1 wherein the second surface comprises a polished silicon bearing surface.

10. The method of claim 1 further comprising reducing a thickness of the second substrate to a predetermined thickness.

11. The method of claim 1 wherein each of the plurality of second chips comprises a plurality of mirror structures, each of the mirror structures being separated by a post structure, each of the post structures having a width of about 1 micron and less.

12. A method for bonding different substrates together to manufacture display devices for visual imaging applications, the method comprising:
providing a first substrate comprising a first surface, the first substrate comprising a plurality of first chips thereon, each of the chips comprising integrated circuit devices, the first substrate comprising a first alignment mark on the first substrate and a second alignment mark on the first substrate;
providing a second substrate comprising a second surface, the second substrate comprising a plurality of second chips thereon, each of the chips comprising a plurality of mechanical mirror structures, the second substrate comprising a first pattern on the second substrate and a second pattern on the second substrate;
moving the first alignment mark of the first substrate to the first pattern on the second substrate;
moving the second alignment mark of the first substrate to the second pattern on the second substrate;
maintaining substantial parallel alignment between the first surface and the second surface during a portion of time associated with moving the first alignment mark to the first pattern and moving the second alignment mark with the second pattern;
illuminating a portion of at least one of the first substrate or the second substrate with electromagnetic radiation while the first surface is in substantial parallel alignment with the second substrate;
detecting a signal associated with a portion of the electromagnetic radiation;
using the signal associated with the detected portion of the electromagnetic radiation to align the first substrate with the second substrate using at least the first alignment mark and the first pattern or the second alignment mark and the second pattern;
coupling the first substrate with the second substrate by contacting the first surface with the second surface; and
initiating a bond between the first surface with the second surface.

13. The method of claim 12 wherein the electromagnetic radiation comprises infrared radiation.

14. The method of claim 12 wherein the first alignment mark and the second alignment mark comprise patterned aluminum.

15. The method of claim 12 wherein the coupling brings the first face in contact with the second face using an action in a direction normal to the first surface and the second surface.

16. The method of claim 15 wherein the coupling occurs using only the normal direction for a distance of less than 30 microns.

17. The method of claim 12 wherein the bonding occurs using room temperature.

18. The method of claim 12 wherein the bonding further comprises annealing the first substrate and the second substrate to permanently bond the first surface to the second surface.

19. The method of claim 12 wherein the first surface comprises a deposited oxide, the deposited oxide being planarized.

20. The method of claim 12 wherein the second surface comprises a polished silicon bearing surface.

21. The method of claim 12 further comprising reducing a thickness of the second substrate to a predetermined thickness.
